(19) United States
(12) Patent Application Publication
(10) Pub. No.: US 2019/0027576 A1
(43) Pub. Date: Jan. 24, 2019

(54) COMPOSITE CHANNEL METAL-OXIDE-SEMICONDUCTOR FIELD EFFECT TRANSISTOR (MOSFET)

(71) Applicant: QUALCOMM Incorporated, San Diego, CA (US)

(72) Inventors: Bin YANG, San Diego, CA (US); Xia LI, San Diego, CA (US); Gengming TAO, San Diego, CA (US)

(21) Appl. No.: 15/710,271

(22) Filed: Sep. 20, 2017

Related U.S. Application Data
(60) Provisional application No. 62/535,587, filed on Jul. 21, 2017.

(51) Int. Cl. H01L 29/66; H01L 29/778

(52) U.S. Cl. CPC H01L 29/66431; H01L 29/778; H01L 29/66462

(57) ABSTRACT

A metal-oxide-semiconductor field effect transistor (MOSFET) device may include a substrate. A composite multilayer channel material may be on the substrate. The composite multilayer channel material may include a channel region, a source region, and a drain region. A gate may be on the channel region of the composite multilayer channel material.

### CROSS-REFERENCE TO RELATED APPLICATION

The present application claims the benefit of U.S. Provisional Patent Application No. 62/535,587, filed on Jul. 21, 2017, and titled “COMPOSITE CHANNEL METAL-OXIDE-SEMICONDUCTOR FIELD EFFECT TRANSISTOR (MOSFET),” the disclosure of which is expressly incorporated by reference herein in its entirety.

### BACKGROUND

### Field

Aspects of the present disclosure relate to semiconductor devices, and more particularly to metal-oxide-semiconductor field effect transistors (MOSFETs) having a composite channel.

### Background

Mobile radio frequency (RF) chip designs (e.g., mobile RF transceivers), including MOSFETs, have migrated to a deep sub-micron process node due to cost and power consumption considerations. The design of such mobile RF transceivers becomes complex at this deep sub-micron process node. The design complexity of these mobile RF transceivers is further complicated by added circuit functions to support communication enhancements, such as carrier aggregation. Further design challenges for mobile RF transceivers include analog/RF performance considerations, including mismatch, noise and other performance considerations. The design of these mobile RF transceivers includes the use of additional active devices, for example, to suppress resonance, and/or to perform filtering, bypassing and coupling.

Conventional MOSFET channel materials exhibit lower than desired electron channel mobility. There exists a need for MOSFET channel materials with improved electron channel mobility for applications beyond a five (5) nanometer process node.

### SUMMARY

A metal-oxide-semiconductor field effect transistor (MOSFET) device may include a substrate. A composite multilayer channel material may be on the substrate. The composite multilayer channel material may include a channel region, a source region, and a drain region. A gate may be on the channel region of the composite multilayer channel material.

A method of fabricating a metal-oxide-semiconductor field effect transistor (MOSFET) device may include epitaxially growing a high mobility material layer on a first graphene layer. The method may include epitaxially growing a semiconductor layer on a second graphene layer. The method may also include removing the high mobility material layer from the first graphene layer. The method may also include removing the semiconductor layer from the second graphene layer. The method may also include mechanically bonding the high mobility material layer to a substrate. The method may further include mechanically bonding the semiconductor layer to the high mobility material layer to create a composite multilayer channel material. The method may further include forming the MOSFET device using the composite multilayer channel material.

A metal-oxide-semiconductor field effect transistor (MOSFET) device may include a substrate. A composite multilayer channel material may be on the substrate. The composite multilayer channel material may include means for interfacing with a gate. The composite multilayer channel material may further include means for conducting electrons between a source and a drain of the MOSFET device. The gate may be on the interfacing means of the composite multilayer channel material.

Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer.

FIG. 2 illustrates a cross-sectional view of a die.

FIG. 3 illustrates a cross-sectional view of a metal-oxide-semiconductor field effect transistor (MOSFET) device.

FIG. 4 illustrates a fin field effect transistor (FinFET).

FIG. 5 illustrates a metal-oxide-semiconductor field effect transistor (MOSFET) device including a composite channel according to aspects of the present disclosure.

FIGS. 6A-6M illustrate a fabrication process for a metal-oxide-semiconductor field effect transistor (MOSFET) device including a composite channel according to aspects of the present disclosure.

FIG. 7 illustrates a method for fabricating a metal-oxide-semiconductor field effect transistor (MOSFET) device including a composite channel according to aspects of the present disclosure.

FIG. 8 is a block diagram showing an exemplary wireless communication system in which an aspect of the disclosure may be advantageously employed.

FIG. 9 is a block diagram illustrating a design workstation used for circuit, layout, and logic design of a fin-based structure according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described herein, the use of the term “and/or” is intended to represent an “inclusive OR”, and the use of the term “or” is intended to represent an “exclusive OR”. As described herein, the term “exemplary” used throughout this description means “serving as an example, instance, or illustration,” and should not necessarily be construed as preferred or advantageous over other exemplary configurations. The term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

Fabrication of mobile radio frequency (RF) chips (e.g., mobile RF transceivers) becomes complex at deep sub-micron process nodes due to cost and power consumption considerations. A mobile RF transceiver may include a transmit section for data transmission and a receive section for data reception. For data transmission, the transmit section may modulate an RF carrier signal with data to obtain a modulated RF signal, amplify the modulated RF signal to obtain an amplified RF signal having the proper output power level, and transmit the amplified RF signal via an antenna to a base station. For data reception, the receive section may obtain a received RF signal via the antenna and may amplify and process the received RF signal to recover data sent by the base station.

While an increased amount of data is provided to the end user, successful implementation of carrier aggregation involves advanced RF switches in a mobile RF transceiver. For example, in a mobile RF transceiver, a communication signal is amplified and transmitted by a transmit section. The transmit section may include one or more circuits (e.g., RF switches) that route the communication signal through the transmission paths of the RF transceiver. RF switches may include one or more transistors configured in various ways to route the communication signal. The transistors configured to switch the communication signal are generally fabricated using complementary metal-oxide-semiconductor (CMOS) technology for operating at substantially higher frequencies.

Silicon (Si), germanium (Ge), and SiGe may be used as channel materials of metal-oxide-semiconductor field effect transistors (MOSFETs) in CMOS applications. These elemental semiconductor materials, however, may experience intrinsically lower channel mobility than III-V compound semiconductor materials, such as gallium arsenide (GaAs) and indium gallium arsenide (InGaAs). This lower channel mobility limits performance of elemental semiconductor channel materials at a five (5) nanometer (nm) process node. In particular, there are no current solutions for elemental semiconductor channel materials beyond the five nanometer process node. This is problematic as technology continues shrinking.

Due to their higher channel mobility, III-V compound semiconductor channel material MOSFET devices may be used as the transistors of an RF switch. While III-V compound semiconductor channel materials exhibit higher channel mobility, in CMOS technology, III-V compound semiconductor channel materials suffer from an intrinsically higher interface state density with a gate dielectric material (e.g., a gate oxide). The lack of a reliable gate dielectric on a III-V compound semiconductor channel material is, therefore, an issue for further III-V channel MOSFET development. As a result, there is also no solution for supporting III-V compound semiconductor channel MOSFETs beyond the five nanometer process node.

Aspects of the present disclosure may address these problems by growing high quality epitaxial (EPI) layers of elemental semiconductor materials (e.g., group IV elements) as well as compound semiconductor materials (e.g., group III-V elements), separately on graphene, and then mechanically layer transferring each onto a substrate (e.g., Si, aluminum oxide (Al₂O₃), or other dielectric substrate material). The substrate may be a semiconductor substrate. In aspects of the present disclosure, a multi-layer EPI transfer technique may form composite multi-layer materials, such as Si/InGaAs/Si layers, without any defects between the layers. These composite layers may then form a composite channel layer for a MOSFET device.

According to additional aspects, a gate dielectric may be included on an exposed elemental semiconductor layer (e.g., Si). The use of the exposed elemental semiconductor layer enables formation of a gate dielectric-to-Si interface with a lower interface state density, such as a hafnium oxide (HfO₂)—Si interface. This takes advantage of the composite Si/InGaAs/Si channel, and confines electrons in, for example, the InGaAs layer. The composite channel MOSFET device exhibits a higher electron channel mobility as well as a higher drive current.

It will be understood that the term “layer” includes film and is not to be construed as indicating a vertical or horizontal thickness unless otherwise stated. As described herein, the term “substrate” may refer to a substrate of a diced wafer or may refer to the substrate of a wafer that is not diced. Similarly, the terms wafer and die may be used interchangeably.

According to aspects of the present disclosure, a metal-oxide-semiconductor field effect transistor (MOSFET) device may include a semiconductor substrate and a composite channel (e.g., a composite multi-layer channel material) on the semiconductor substrate. The composite channel may include an elemental semiconductor material layer and a compound semiconductor layer on the semiconductor substrate. A gate may also be formed on the elemental semiconductor material layer of the composite channel. According to aspects of the present disclosure, the elemental semiconductor material layer may include group IV elements, such as Si, Ge, or SiGe. The compound semiconductor material layer may include a high mobility material (e.g., a III-V semiconductor compound material layer), including InGaAs, GaAs, InP, InSb, or GaN.

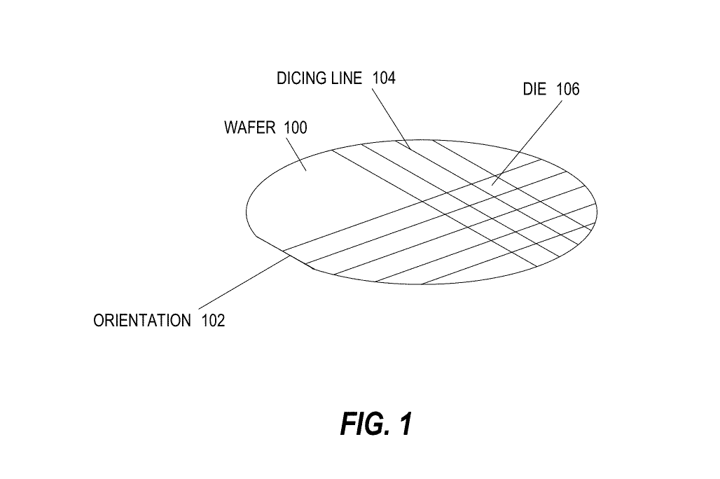

FIG. 1 illustrates a perspective view of a semiconductor wafer. A wafer 100 may be a semiconductor wafer, or may be a substrate material (e.g., Si, Al₂O₃, or other dielectric substrate) with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be a compound material, such as gallium arsenide (GaAs) or gallium nitride (GaN), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100.

The Miller Indices form a notation system of the crystallographic planes in crystal lattices. The lattice planes may be indicated by three integers h, k, and f, which are the Miller indices for a plane (hkl) in the crystal. Each index denotes a plane orthogonal to a direction (h, k, l) in the basis of the reciprocal lattice vectors. The integers are usually written in lowest terms (e.g., their greatest common divisor should be 1). Miller index 100 represents a plane orthogonal to direction h; index 010 represents a plane orthogonal to direction k, and index 001 represents a plane orthogonal to l. For some crystals, negative numbers are used (written as a bar over the index number) and for some crystals, such as gallium nitride, more than three numbers may be employed to adequately describe the different crystallographic planes.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

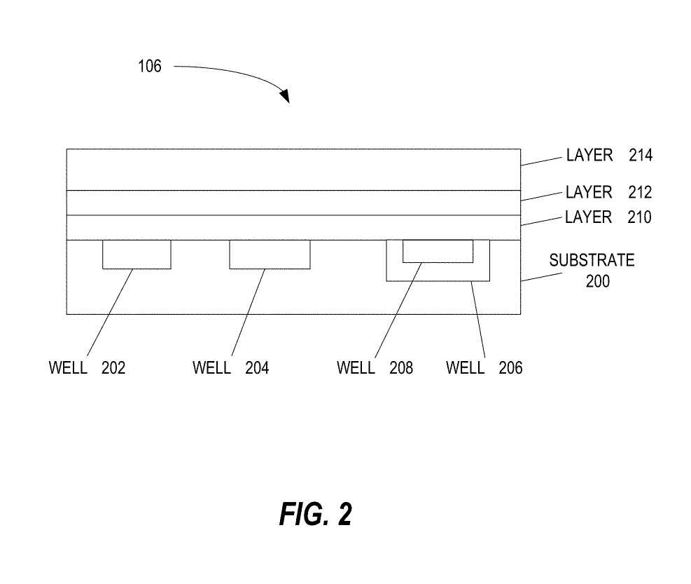

FIG. 2 illustrates a cross-sectional view of a die 106. In the die 106, there may be a substrate 200 (e.g., a semiconductor substrate), which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within the substrate 200, there may be wells 202 and 204 of a field effect transistor (FET), or wells 202 and/or 204 may be fin structures of a fin structured FET (FinFET). Wells 202 and/or 204 may also be other devices (e.g., a resistor, a capacitor, a diode, or other electronic devices) depending on the structure and other characteristics of the wells 202 and/or 204 and the surrounding structure of the substrate 200.

The substrate 200 may also have a well 206 and a well 208. The well 208 may be completely within the well 206, and, in some cases, may form a bipolar junction transistor (BJT). The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

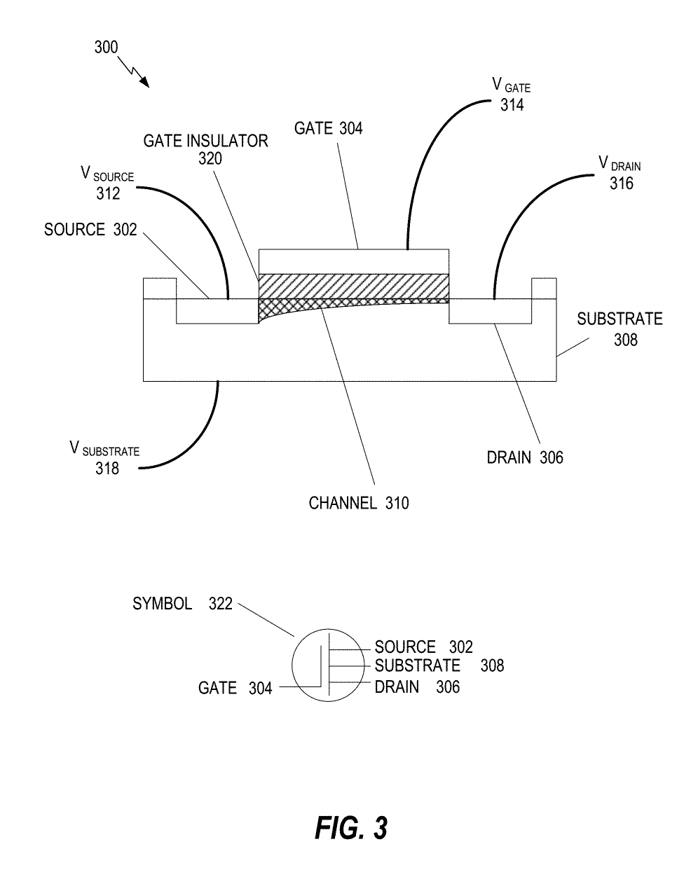

FIG. 3 illustrates a cross-sectional view of a metal-oxide-semiconductor field effect transistor (MOSFET) device 300. The MOSFET device 300 may have four input terminals. The four inputs are a source 302, a gate 304, a drain 306, and a body. The source 302 and the drain 306 may be fabricated as the wells 202 and 204 in a substrate 308, or may be fabricated as areas above the substrate 308, or as part of other layers on the die 106. Such other structures may be a fin or other structure that protrudes from a surface of the substrate 308. Further, the substrate 308 may be the substrate 200 on the die 106, but substrate 308 may also be one or more of the layers (e.g., 210-214) that are coupled to the substrate 200.

The MOSFET device 300 is a unipolar device, as electrical current is produced by only one type of charge carrier (e.g., either electrons or holes) depending on the type of MOSFET. The MOSFET device 300 operates by controlling the amount of charge carriers in the channel 310 between the source 302 and the drain 306. A voltage Vsource 312 is applied to the source 302, a voltage Vgate 314 is applied to the gate 304, and a voltage Vdrain 316 is applied to the drain 306. A separate voltage Vsubstrate 318 may also be applied to the substrate 308, although the voltage Vsubstrate 318 may be coupled to one of the voltage Vsource 312, the voltage Vgate 314 or the voltage Vdrain 316.

To control the charge carriers in the channel 310, the voltage Vgate 314 creates an electric field in the channel 310 when the gate 304 accumulates charges. The opposite charge to that accumulating on the gate 304 begins to accumulate in the channel 310. The gate insulator 320 insulates the charges accumulating on the gate 304 from the source 302, the drain 306, and the channel 310. The gate 304 and the channel 310, with the gate insulator 320 in between, create a capacitor, and as the voltage Vgate 314 increases, the charge carriers on the gate 304, acting as one plate of this capacitor, begin to accumulate. This accumulation of charges on the gate 304 attracts the opposite charge carriers into the channel 310. Eventually, enough charge carriers are accumulated in the channel 310 to provide an electrically conductive path between the source 302 and the drain 306. This condition may be referred to as opening the channel of the FET.

By changing the voltage Vsource 312 and the voltage Vdrain 316, and their relationship to the voltage Vgate 314, the amount of voltage applied to the gate 304 that opens the channel 310 may vary. For example, the voltage Vsource 312 is usually of a higher potential than that of the voltage Vdrain 316. Making the voltage differential between the voltage Vsource 312 and the voltage Vdrain 316 larger will change the amount of the voltage Vgate 314 used to open the channel 310. Further, a larger voltage differential will change the amount of electromotive force moving charge carriers through the channel 310, creating a larger current through the channel 310.

The gate insulator 320 material may be silicon oxide, or may be a dielectric or other material with a different dielectric constant (k) than silicon oxide. Further, the gate insulator 320 may be a combination of materials or different layers of materials. For example, the gate insulator 320 may be Aluminum Oxide, Hafnium Oxide, Hafnium Oxide Nitride, Zirconium Oxide, or laminates and/or alloys of these materials. Other materials for the gate insulator 320 may be used without departing from the scope of the present disclosure.

By changing the material for the gate insulator 320, and the thickness of the gate insulator 320 (e.g., the distance between the gate 304 and the channel 310), the amount of charge on the gate 304 to open the channel 310 may vary. A symbol 322 showing the terminals of the MOSFET device 300 is also illustrated. For N-channel MOSFETs (using electrons as charge carriers in the channel 310), an arrow is applied to the substrate 308 terminal in the symbol 322 pointing away from the gate 304 terminal. For P-channel MOSFETs (using holes as charge carriers in the channel 310), an arrow is applied to the substrate 308 terminal in the symbol 322 pointing toward the gate 304 terminal.

The gate 304 may also be made of different materials. In some designs, the gate 304 is made from polycrystalline silicon, also referred to as polysilicon or poly, which is a conductive form of silicon. Although referred to as “poly” or “polysilicon” herein, metals, alloys, or other electrically conductive materials are contemplated as appropriate materials for the gate 304 as described in the present disclosure.

In some MOSFET designs, a high-k value material may be desired in the gate insulator 320, and in such designs, other conductive materials may be employed. For example, and not by way of limitation, a “high-k metal gate” design may employ a metal, such as copper, for the gate 304. Although referred to as “metal,” polycrystalline materials, alloys, or other electrically conductive materials are contemplated as appropriate materials for the gate 304 as described in the present disclosure.

To interconnect to the MOSFET device 300, or to interconnect to other devices in the die 106 (e.g., semiconductor), interconnect traces or layers are used. These interconnect traces may be in one or more of layers (e.g., 210-214), or may be in other layers of the die 106. The MOSFET device 300 may be a MOSFET with a composite channel, as disclosed herein.

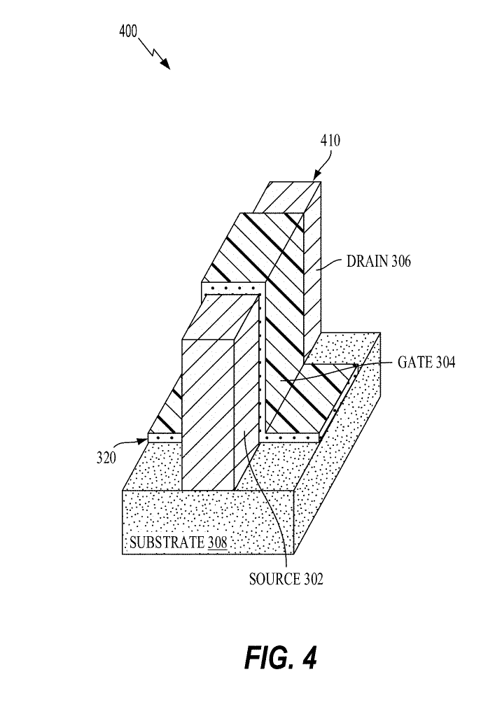

FIG. 4 illustrates a fin-structured FET (FinFET) 400 that operates in a similar fashion to the MOSFET device 300 described with respect to FIG. 3. A fin 410 in a FinFET 400, however, is grown or otherwise coupled to the substrate 308. The substrate 308 may be a semiconductor substrate or other like supporting layer, for example, comprised of an oxide layer, a nitride layer, a metal oxide layer or a silicon layer. The fin 410 includes the source 302 and the drain 306. A gate 304 is disposed on the fin 410 and on the substrate 308 through a gate insulator 320. A FinFET transistor is a 3D fin-based metal-oxide-semiconductor field effect transistor (MOSFET). As a result, the physical size of the FinFET 400 may be smaller than the MOSFET device 300 structure shown in FIG. 3.

Silicon (Si), germanium (Ge), and SiGe may be used as channel materials of metal-oxide-semiconductor field effect transistors (MOSFETs) in complementary metal-oxide-semiconductor (CMOS) applications. These elemental semiconductor materials, however, may experience intrinsically lower channel mobility than III-V compound semiconductor materials, such as gallium arsenide (GaAs) and indium gallium arsenide (InGaAs). This lower channel mobility limits performance of elemental semiconductor channel materials at a five nanometer (nm) process node. In particular, there are no current solutions for elemental semiconductor channel materials beyond the five nanometer process node.

Due to their higher channel mobility, III-V compound semiconductor channel material MOSFET devices may be used as the transistors of a switch (e.g., an RF switch). While III-V compound semiconductor channel materials exhibit higher channel mobility, in CMOS technology, III-V compound semiconductor channel materials suffer from an intrinsically higher interface state density with a gate dielectric material (e.g., a gate oxide). The lack of a reliable gate dielectric on a III-V compound semiconductor channel material is, therefore, an issue for further III-V channel MOSFET development. As a result, there is also no solution for supporting III-V compound semiconductor channel MOSFETs beyond the five nanometer process node.

Aspects of the present disclosure may address these problems by growing high quality epitaxial (EPI) layers of elemental semiconductor materials (e.g., group IV elements) as well as compound semiconductor materials (e.g., group III-V elements), separately on graphene, and then mechanically layer transferring each onto a substrate. The hexagonal lattice structure of graphene enables other materials to be grown on graphene without a template. The substrate may be a semiconductor substrate (e.g., Si, aluminum oxide (Al₂O₃)), or may be composed of another dielectric substrate.

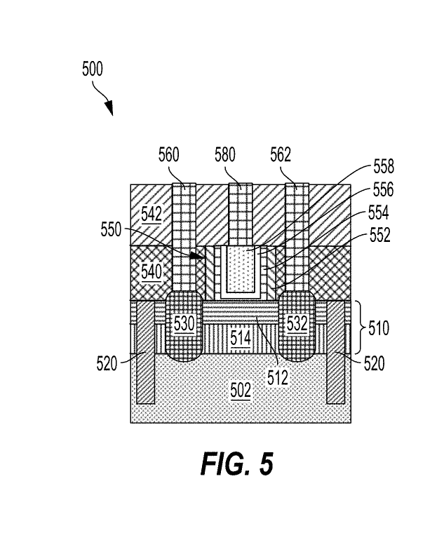

FIG. 5 illustrates a metal-oxide-semiconductor field effect transistor (MOSFET) device 500 including a composite multilayer channel material 510, according to aspects of the present disclosure. The composite multilayer channel material 510 may include a first layer 512 (e.g., an elemental semiconductor material layer) and a second layer 514 (e.g., a compound semiconductor material layer), which may be referred to as a high mobility layer. As described, “an elemental semiconductor material layer” may refer to a layer of semiconductor material (e.g., Si or Ge) found in group IV of the periodic table, or a combination of semiconductor materials (e.g., SiGe) found in group IV of the periodic table. As described, “a compound semiconductor material layer” may refer to a layer of a combination of semiconductor material elements (e.g., InGaAs, GaAs, InP (indium phosphide), InSb (indium antimonide), or GaN (gallium nitride)) found in group III and group V of the periodic table, which generally exhibit higher electron mobility than elemental semiconductor materials.

According to additional aspects of the present disclosure, the composite multilayer channel material 510 may include multiple epitaxially grown layers. For example, the first layer 512 of an elemental semiconductor material layer may be grown on a donor wafer. In addition, the second layer 514 of a compound semiconductor material layer may be epitaxially grown separately on another donor wafer. Once grown, the first layer 512 and the second layer 514 may be pealed from their respective donor wafers, and then mechanically bonded together to form the composite multilayer channel material 510.

The MOSFET device 500 may include a substrate 502 (e.g., a semiconductor substrate) supporting the composite multilayer channel material 510. For example, the second layer 514 of the composite multilayer channel material 510 may be mechanically bonded to an exposed surface of the substrate 502. The composite multilayer channel material 510 further includes a source region 530, a drain region 532, and a channel region between the source region 530 and the drain region 532. Isolation regions 520 (e.g., a shallow trench isolation (STI) region) may extend through the composite multilayer channel material 510 into the substrate 502 to provide isolation from other active devices.

A gate 550 may be on the composite multilayer channel material 510, including a gate oxide layer 554 for interfacing the gate 550 with the elemental semiconductor material layer (e.g., 512) of the composite multilayer channel material 510. The use of an elemental semiconductor material as the first layer 512 of the composite multilayer channel material 510 enables forming of a gate dielectric-to-elemental semiconductor interface with a lower interface state density, which confines electrons in the compound semiconductor material of the second layer 514. In this example, the gate 550 includes a pair of spacers 552, the gate oxide layer 554, a metal gate layer 556, and a gate fill material 558. The gate oxide layer 554 may include a high-K dielectric.

According to additional aspects of the disclosure, the MOSFET device 500 may include a first dielectric layer 540 deposited on the gate 550 and the composite multilayer channel material 510. In addition, a second dielectric layer 542 is deposited on an exposed portion of the gate 550 and the first dielectric layer 540. In this example, a source contact 560 and a drain contact 562 may extend through the first dielectric layer 540 and the second dielectric layer 542 to contact the source region 530 and the drain region 532. A gate contact 580 may extend through the second dielectric layer 542 to contact the gate fill material 558 of the gate 550. The source contact 560, the drain contact 562, and the gate contact 580 may be vias. Doping of the source contact 560 and the drain contact 562 may be standard doping.

According to aspects of the present disclosure, the gate oxide layer 554 is deposited on the exposed elemental semiconductor layer (e.g., 512) of the composite multilayer channel material 510. The use of the exposed elemental semiconductor layer enables formation of a gate oxide-to-elemental semiconductor interface with a lower interface state density, such as a hafnium oxide (HfO₂-Si interface. This takes advantage of the composite multilayer channel material (e.g., Si/InGaAs/Si) channel, and confines electrons in, for example, the InGaAs layer (e.g., 514). Advantages of this configuration of the MOSFET device 500 include higher electron mobility in the composite channel (e.g., III-V/IV interface) for MOSFET devices, which allows for CMOS scaling beyond the five nanometer node. Advantages also include improvements in MOSFET performance over non-reliable oxide-III-V interfaces of conventional III-V MOSFET devices.

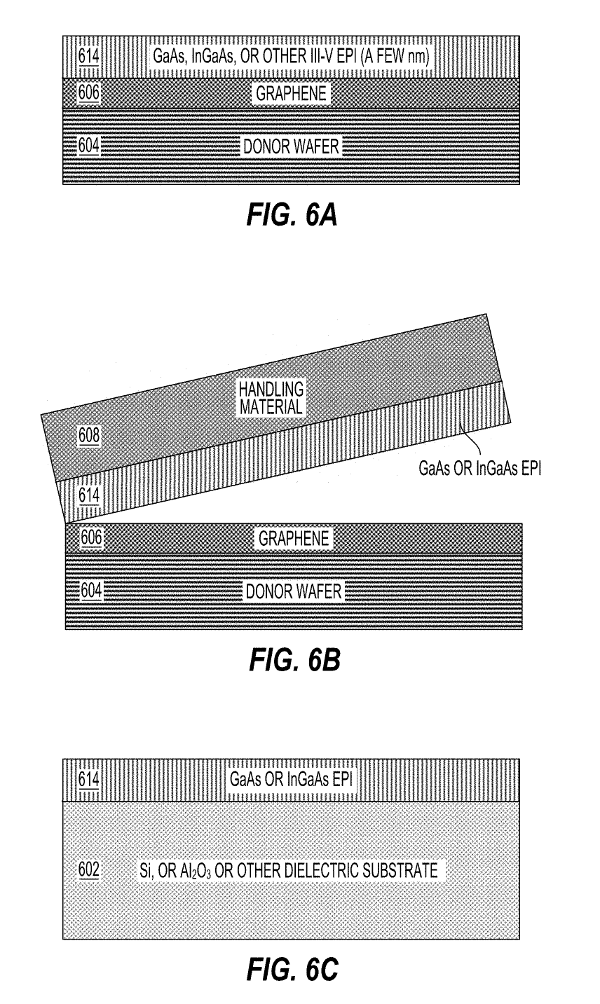

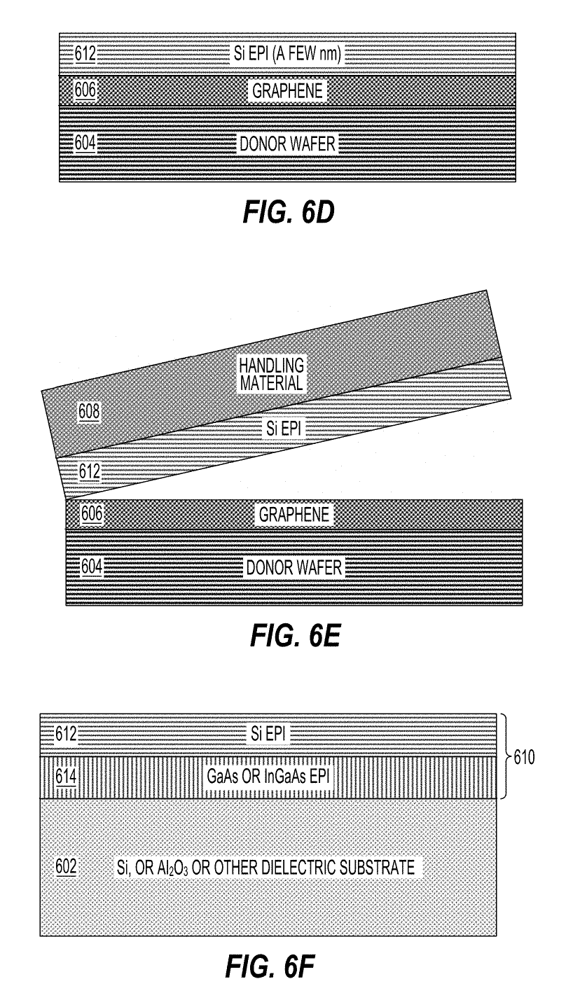

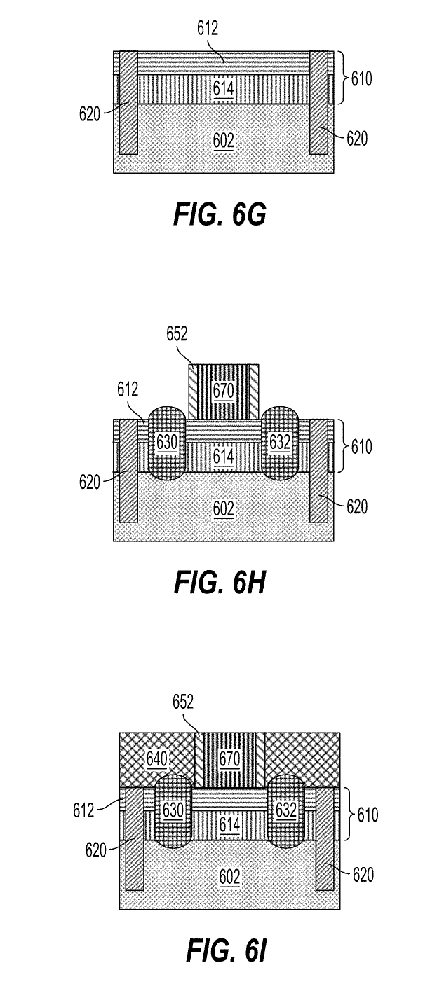

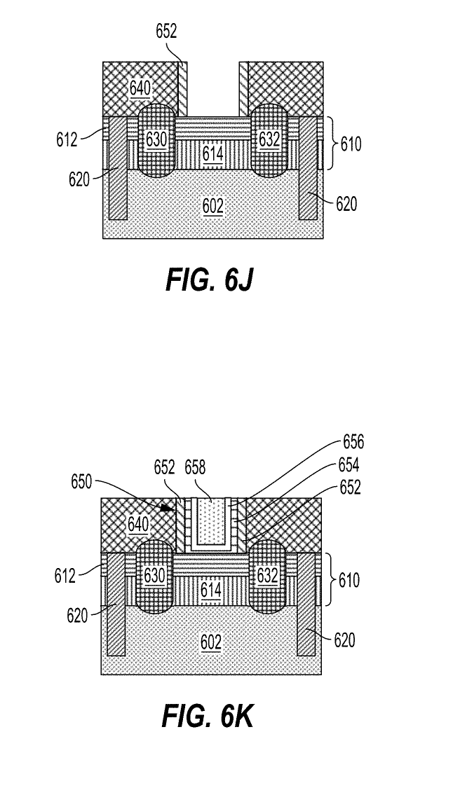

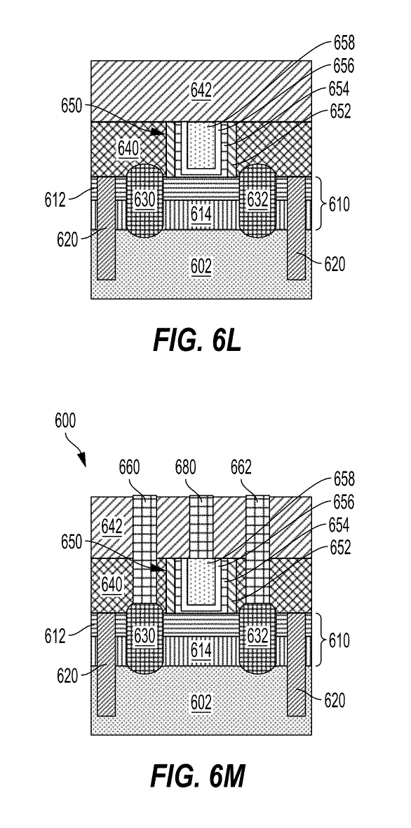

FIGS. 6A-6M illustrate a fabrication process for a metal-oxide-semiconductor field effect transistor (MOSFET) device including a composite multilayer channel material 610 according to aspects of the present disclosure.

Referring to FIGS. 6A-6C, a high mobility material layer 614 is epitaxially grown on a graphene layer 606. The graphene layer 606 may be formed on a donor wafer 604. For example, the high mobility material layer 614 may be GaAs, InGaAs, InP, InSb, GaN, or any other III-V compound semiconductor material. The high mobility material layer 614 may be a few nanometers thick. For example, the high mobility material layer 614 may be 2 nm to 20 nm. Of course this range is exemplary, and other thicknesses are possible. A handle substrate 608 (e.g., glass or Si) may mechanically exfoliate the high mobility material layer 614 from the graphene layer 606. The high mobility material layer 614 may then be mechanically bonded (e.g., heat bonded) to a substrate 602. For example, the substrate may be Si, Al₂O₃, or any other dielectric substrate.

Referring to FIGS. 6D-6F, an elemental semiconductor material layer 612 (e.g., Si, Ge, SiGe) is epitaxially grown on the graphene layer 606, which was formed on the donor wafer 604. The elemental semiconductor material layer 612 may be a few nanometers thick. For example, the elemental semiconductor material layer 612 may be 0.5 nm to 5 nm thick. Of course this range is exemplary, and other thicknesses are possible. The handle substrate 608 (e.g., glass or Si) may mechanically exfoliate the elemental semiconductor material layer 612 from the graphene layer 606. The elemental semiconductor material layer 612 may then be mechanically bonded (e.g., head bonded) to the high mobility material layer 614 to form a composite multilayer channel material 610. The elemental semiconductor material layer 612 may be substantially thinner than the high mobility material layer 614 to serve as an interface layer between the composite multilayer channel material 610 and the rest of the MOSFET device 600 (as shown in FIG. 6M).

According to aspects of the present disclosure, the high mobility material layer 614 and the elemental semiconductor material layer 612 may be simultaneously formed on separate graphene layers of donor wafers. For example, the high mobility material layer 614 may be formed on a first graphene layer of a first donor wafer, and the elemental semiconductor material layer 612 may be formed on a second graphene layer of a second donor wafer. This way, the high mobility material layer 614 and the elemental semiconductor material layer 612 may be simultaneously formed and exfoliated. Alternatively, the high mobility material layer 614 and the elemental semiconductor material layer 612 may both be formed on the same graphene layer of a donor wafer. In this case, the high mobility material layer 614 may first be fabricated, exfoliated, and bonded to the substrate 602, prior to fabricating, exfoliating, and bonding the elemental semiconductor material layer 612 to the high mobility material layer 614 on the substrate 602.

According to additional aspects of the present disclosure, the same handle substrate 608 may remove the high mobility material layer 614 and the elemental semiconductor material layer 612, or different handle substrates may be used. For example, if the high mobility material layer 614 and the elemental semiconductor material layer 612 are simultaneously fabricated, then different handle substrates remove the high mobility material layer 614 and the elemental semiconductor material layer 612. If the high mobility material layer 614 and the elemental semiconductor material layer 612 are fabricated consecutively on the same graphene layer 606, then the same handle substrate 608 may remove both the high mobility material layer 614 and the elemental semiconductor material layer 612.

Referring to FIGS. 6G-6I, shallow trench isolation (STI) regions 620 are formed through the composite multilayer channel material 610 and into the substrate 602. A source region 630 and a drain region 632 are additionally formed in the composite multilayer channel material 610.

According to an aspect, the source region 630 and the drain region 632 may be formed by first etching through portions of the elemental semiconductor material layer 612 and the high mobility material layer 614 to create trenches. The source region 630 and the drain region 632 are then epitaxially grown and embedded in the trenches. For example, the source region 630 and the drain region 632 may be N+ doped for NMOS, or P+ doped for PMOS. The epitaxial material of the source region 630 and the drain region 632 may depend on the high mobility material layer 614. For example, if the high mobility material layer 614 is InGaAs, then the source region 630 and the drain region 632 may be N+ doped InGaAs for NMOS, or P+ doped InGaAs for PMOS. As another example, if the high mobility material layer 614 is InSb, then the source region 630 and the drain region 632 may be N+ doped InSb for NMOS, or P+ doped InSb for PMOS.

Gate spacers 652 and a dummy gate 670 may be formed over the elemental semiconductor material layer 612 of the composite multilayer channel material 610. A first dielectric layer 640 (e.g., an inter-layer dielectric) may be formed over the composite multilayer channel material 610, and a chemical mechanical polish (CMP) may planarize a surface of the first dielectric layer 640.

Referring to FIGS. 6J-6K, the dummy gate 670 is removed through, for example, a wet etch process. Subsequently, a gate 650 is formed by depositing a gate dielectric 654 (e.g., a high-K dielectric layer) on the elemental semiconductor material layer 612 and on sidewalls of the gate spacers 652. For example, the elemental semiconductor material layer 612 may interface with the gate dielectric 654. A metal gate material layer 656 may be deposited over the gate dielectric 654, and a metal gate fill material 658 may be deposited over the metal gate material layer 656.

Referring to FIGS. 6L-6M, a second dielectric layer 642 (e.g., an inter-layer dielectric) is deposited over the first dielectric layer 640. A source contact 660 and a drain contact 662 are then formed through the first dielectric layer 640 and the second dielectric layer 642 to contact the source region 630 and the drain region 632. A gate contact 680 may be formed through the second dielectric layer 642 to contact the metal gate fill material 658 of the gate 650. For example, the source contact 660, the drain contact 662, and gate contact 680 may be vias.

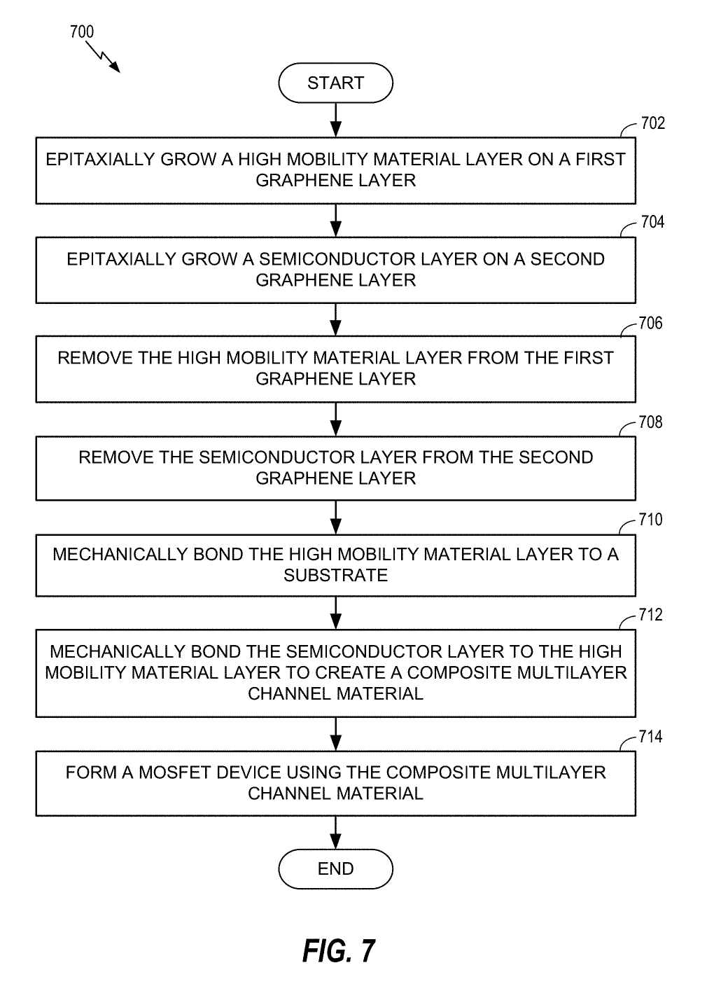

In aspects of the present disclosure, a multi-layer epitaxial transfer technique may form composite multi-layer materials, such as Si/InGaAs/Si layers, without any defects between the layers. These composite channel layers may then form a composite channel layer for a MOSFET device. The elemental semiconductor material layer 612 should have a reduced thickness, as its primary purpose is the interface between the gate 650 and the compound semiconductor material layer of high mobility material layer 614. The compound semiconductor material layer of the high mobility material layer 614 should be thicker because of its higher mobility. That is, the majority of the composite multilayer channel material 610 should be the compound semiconductor material layer of the high mobility material layer 614. A process for fabricating a composite channel MOSFET device is shown in FIG. 7.

FIG. 7 is a process flow diagram illustrating a method 700 of fabricating a composite channel MOSFET device, according to aspects of the present disclosure. The method 700 may include, at block 702, epitaxially growing a high mobility material layer (e.g., a III-V compound semiconductor layer) on a first graphene layer. For example, the high mobility material layer 614 may be epitaxially grown on the graphene layer 606, as shown in FIG. 6A.

At block 704, a semiconductor layer (e.g., a Si layer) is epitaxially grown on a second graphene layer. The semiconductor layer may be substantially thinner than the high mobility material layer. For example, the elemental semiconductor material layer 612 may be epitaxially grown on the graphene layer 606, as shown in FIG. 6D.

At block 706, the high mobility material layer is removed from the first graphene layer. For example, the handle substrate 608 may be bonded to the high mobility material layer 614 to remove the high mobility material layer 614 from the graphene layer 606, as shown in FIG. 6B.

At block 708, the semiconductor layer is removed from the second graphene layer. For example, the handle substrate 608 may be bonded to the elemental semiconductor material layer 612 to remove the elemental semiconductor material layer 612 from the graphene layer 606, as shown in FIG. 6E.

At block 710, the high mobility material layer is mechanically bonded to a substrate (e.g., a semiconductor). For example, the high mobility material layer 614 may be bonded to the substrate 602, as shown in FIG. 6C. According to aspects of the present disclosure, the substrate 602 may include Si, Ak₂O₃, or other dielectric material.

At block 712, the semiconductor layer is mechanically bonded to the high mobility material layer to create a composite multilayer channel material. For example, the elemental semiconductor material layer 612 may be bonded to the high mobility material layer 614 to form the composite multilayer channel material 610, as shown in FIG. 6F.

At block 714, the MOSFET device is formed using the composite multilayer channel material. For example, the source region 630 and the drain region 632 may be formed in the composite multilayer channel material 610, and the gate 650 may be formed on the elemental semiconductor material layer 612. In addition, the source contact 660, the drain contact 662, and the gate contact 680 may be formed as illustrated in FIGS. 6H-6M.

According to aspects of the present disclosure, the first graphene layer and the second graphene layer may be the same graphene layer, or may be different graphene layers.

According to an aspect of the present disclosure, a metal-oxide-semiconductor field effect transistor (MOSFET) device is described. In one configuration, the MOSFET device includes means for interfacing with a gate and means for conducting electrons between a source and a drain of the MOSFET device. The interfacing means may be the first layer 512, as shown in FIG. 5. The conducting means may be the second layer 514, as shown in FIG. 5. In another aspect, the aforementioned means may be any module or any apparatus or material configured to perform the functions recited by the aforementioned means.

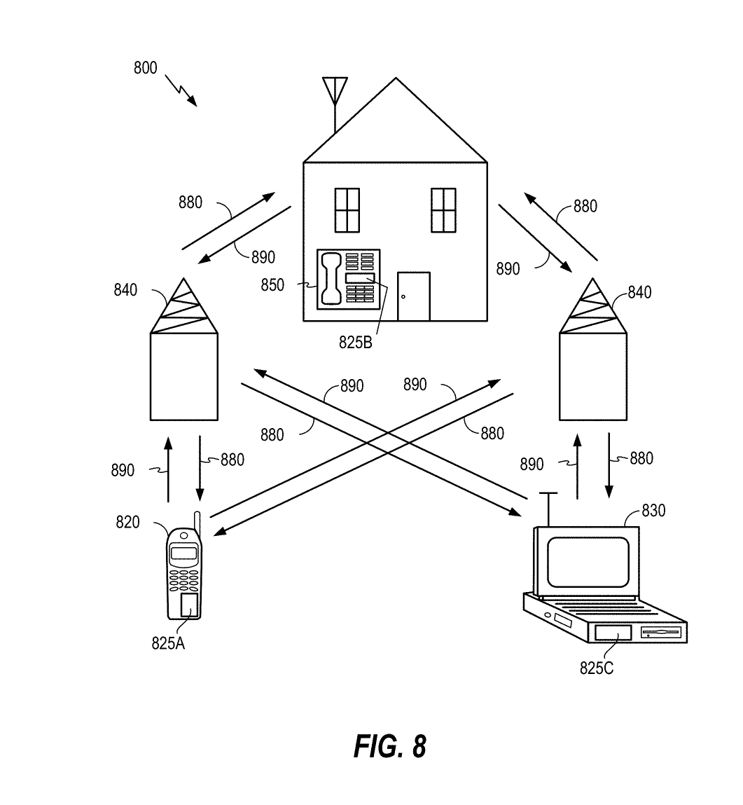

FIG. 8 is a block diagram showing an exemplary wireless communication system 800 in which aspects of the present disclosure may be advantageously employed. For purposes of illustration, FIG. 8 shows three remote units 820, 830, and 850 and two base stations 840. It will be recognized that wireless communication systems may have many more remote units and base stations. Remote units 820, 830, and 850 include IC devices 825A, 825C, and 825B that include the disclosed composite channel MOSFET device. It will be recognized that other devices may also include the disclosed composite channel MOSFET device, such as the base stations, switching devices, and network equipment. FIG. 8 shows forward link signals 880 from the base station 840 to the remote units 820, 830, and 850 and reverse link signals 890 from the remote units 820, 830, and 850 to base station 840.

In FIG. 8, remote unit 820 is shown as a mobile telephone, remote unit 830 is shown as a portable computer, and remote unit 850 is shown as a fixed location remote unit in a wireless local loop system. For example, the remote units may be a mobile phone, a hand-held personal communication systems (PCS) unit, a portable data unit such as a personal data assistant, a GPS enabled device, a navigation device, a set top box, a music player, a video player, an entertainment unit, a fixed location data unit such as meter reading equipment, or other devices that store or retrieve data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the disclosed composite channel MOSFET device.

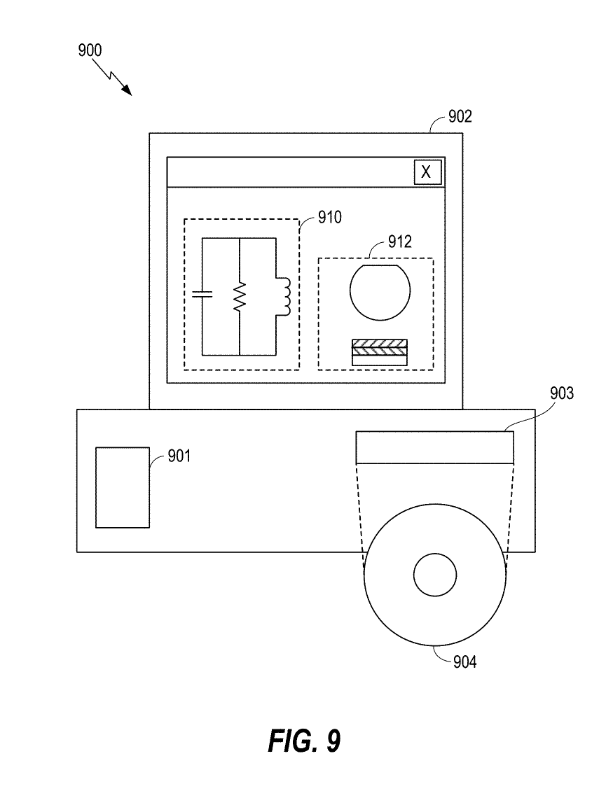

FIG. 9 is a block diagram illustrating a design workstation used for circuit, layout, and logic design of an IC structure, such as the integrated circuit including a MOSFET device disclosed above. A design workstation 900 includes a hard disk 901 containing operating system software, support files, and design software such as Cadence or OrCAD. The design workstation 900 also includes a display 902 to facilitate design of a circuit 910 or an IC device 912 including the disclosed composite channel MOSFET device. A storage medium 904 is provided for tangibly storing the design of the circuit 910 or the IC device 912. The design of the circuit 910 or the IC device 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the IC device 912 including the disclosed composite channel MOSFET device by decreasing the number of processes for designing semiconductor wafers.

For a firmware and/or software implementation, the methodologies may be implemented with modules (e.g., procedures, functions, and so on) that perform the functions described herein. Machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), and Blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

1. A metal-oxide-semiconductor field effect transistor (MOSFET) device, comprising:
a substrate;
a composite multilayer channel material on the substrate, the composite multilayer channel material comprising a first layer and a second layer of a channel region, a source region, and a drain region, in which the first layer interfaces with a gate oxide layer and the second layer is directly on the substrate; and
a gate on the channel region of the composite multilayer channel material.

2. (canceled)

3. The MOSFET device of claim 1, in which the first layer comprises an elemental semiconductor material, and the second layer comprises a high mobility material.

4. The MOSFET device of claim 3, in which the elemental semiconductor material is thinner than the high mobility material.

5. The MOSFET device of claim 3, in which the elemental semiconductor material comprises Si, Ge, or SiGe.

6. The MOSFET device of claim 3, in which the high mobility material comprises a compound semiconductor material including InGaAs, GaAs, InP, InSb, or GaN.

7. The MOSFET device of claim 1, in which the composite multilayer channel material comprises a plurality of epitaxially grown layers.

8. The MOSFET device of claim 1, integrated into a mobile phone, a set top box, a music player, a video player, an entertainment unit, a navigation device, a computer, a hand-held personal communication systems (PCS) unit, a portable data unit, and/or a fixed location data unit.

9. A method of fabricating a metal-oxide-semiconductor field effect transistor (MOSFET) device, comprising:
epitaxially growing a high mobility material layer on a first graphene layer;
epitaxially growing a semiconductor layer on a second graphene layer;
removing the high mobility material layer from the first graphene layer;
removing the semiconductor layer from the second graphene layer;
mechanically bonding the high mobility material layer to a substrate;
mechanically bonding the semiconductor layer to the high mobility material layer to create a composite multilayer channel material; and
forming the MOSFET device using the composite multilayer channel material.

10. The method of claim 9, in which forming the MOSFET device comprises:
forming a dummy gate on the semiconductor layer of the composite multilayer channel material including gate spacers;
depositing an inter-layer dielectric on the dummy gate; and
planarizing the inter-layer dielectric on the dummy gate.

11. The method of claim 10, further comprising:
removing the dummy gate;
depositing a gate dielectric on the semiconductor layer of the composite multilayer channel material and sidewalls of the gate spacers; and
fabricating a metal gate of the MOSFET device on the gate dielectric.

12. The method of claim 11, in which depositing the gate dielectric comprises depositing a high-K dielectric layer on the semiconductor layer of the composite multilayer channel material and on the sidewalls of the gate spacers.

13. The method of claim 9, in which mechanically bonding comprises heat bonding.

14. The method of claim 9, in which removing the high mobility material layer comprises bonding the high mobility material layer to glass or silicon.

15. The method of claim 9, in which removing the semiconductor layer comprises bonding the semiconductor layer to glass or silicon.

16. The method of claim 9, in which the semiconductor layer is thinner than the high mobility material layer.

17. The method of claim 9, in which the MOSFET device is integrated into a mobile phone, a set top box, a music player, a video player, an entertainment unit, a navigation device, a computer, a hand-held personal communication systems (PCS) unit, a portable data unit, and/or a fixed location data unit.

18. A metal-oxide-semiconductor field effect transistor (MOSFET) device, comprising:
a substrate;
a composite multilayer channel material on the substrate, the composite multilayer channel material comprising means for interfacing with a gate and means for conducting electrons between a source and a drain of the MOSFET device, in which the multilayer channel material is directly on the substrate; and
the gate on the interfacing means of the composite multilayer channel material.

19. The MOSFET device of claim 18, in which the means for interfacing comprises a first layer and the means for conducting electrons comprises a second layer, the first layer interfacing with a gate oxide layer.

20. The MOSFET device of claim 19, in which the first layer comprises an elemental semiconductor material, and the second layer comprises a high mobility material.

21. The MOSFET device of claim 20, in which the elemental semiconductor material is thinner than the high mobility material.

22. The MOSFET device of claim 20, in which the elemental semiconductor material comprises Si, Ge, or SiGe.

23. The MOSFET device of claim 20, in which the high mobility material comprises a compound semiconductor material including InGaAs, GaAs, InP, InSb, or GaN.

24. The MOSFET device of claim 18, in which the composite multilayer channel material comprises a plurality of epitaxially grown layers.

25. The MOSFET device of claim 18, integrated into a mobile phone, a set top box, a music player, a video player, an entertainment unit, a navigation device, a computer, a hand-held personal communication systems (PCS) unit, a portable data unit, and/or a fixed location data unit.
